(19) United States
(12) Patent Application Publication
(10) Pub. No.: US 2002/0145160 A1
(43) Pub. Date: Oct. 10, 2002

(54) Nonvolatile memory cell

(76) Inventor: Hsiang-Lan Lung, Hsinchu (TW)

Correspondence Address: BIRCH STEWART KOLASCH & BIRCH, PO BOX 747, FALLS CHURCH, VA, 22040-0747, US

(21) Appl. No.: 10/115,945

(22) Filed: Apr. 5, 2002

(30) Foreign Application Priority Data
Apr. 6, 2001 (TW) 90108278

(51) Int. Cl. H01L 29/76

(52) U.S. Cl. 257/314

(57) ABSTRACT

A nonvolatile memory cell. Using point discharge mode to inject carriers into a charge-trapping dielectric layer, the point discharge occurs from a polysilicon layer.

### BACKGROUND OF THE INVENTION

1. Field of the Invention

The present invention relates in general to a nonvolatile memory, such as electrically erasable programmable read only memory (EEPROM), using point discharge mode to inject carriers into a charge-trapping dielectric layer.

2. Description of the Related Art

Memory devices for non-volatile storage of information are currently in widespread use, in a myriad of applications. A few examples of non-volatile semiconductor memory include read only memory (ROM), programmable read only memory (PROM), erasable programmable read only memory (EPROM), electrically erasable programmable read only memory (EEPROM) and flash EEPROM.

RCM devices, however, suffer from the disadvantage of not being electrically programmable. The programming of a ROM occurs during one of the steps of manufacture using special masks containing the data to be stored. Thus, the entire contents of a ROM must be determined before manufacture. In addition, because ROM devices are programmed during manufacture, there is a time delay before the finished product is available.

The advantage of using ROM for data storage is low cost per device. However, the penalty is an inability to change the data once the masks are committed to. If mistakes in the data programming are found they are typically very costly to correct. Any inventory that exists having incorrect data programming is instantly obsolete and probably cannot be used. In addition, extensive time delays are incurred because new masks must first be generated from scratch and the entire manufacturing process repeated.

Moving to EPROM devices eliminates the necessity of mask programming the data but the complexity of the process increases drastically. In addition, the die size is larger due to the addition of programming circuitry and there are more processing and testing steps involved in the manufacture of these types of memory devices. An advantage of EPROM is that they are electrically programmed, but for erasing, EPROM requires exposure to ultraviolet (UV) light. These devices are constructed with windows transparent to UV light to allow the die to be exposed for erasing, which must be performed before the device can be programmed. A major drawback to these devices is that they lack the ability to be electrically erased. In many circuit designs it is desirable to have a non-volatile memory device that can be erased and reprogrammed in-circuit, without the need to remove the device for erasing and reprogramming.

EEPROM devices have the advantage of electrical programming and erasing, achieved by charging and discharging actions controlled by the control gate. The actions also affect the conductivity of the channel between source and drain. As shown in FIGS. 1A and 1B, charges 106 may remain on the gate 104, therefore, electrons may be stored in the nonconducting structure layer 105 between the gate 104 and substrate 101. There are two ways to inject electrons 107 into the nonconducting structure layer 105, hot-electron injection, and Fowler-Norheim (FN) tunneling effect.

In EPROM devices, as shown in FIGS. 1A and 1B, the floating gates are charged using hot-electron injection and discharged by exposure to UV light. In Flash EEPROM devices, the floating gates are charged using hot-electron injection and discharged using FN tunneling effect. In EEPROM devices, the floating gates are both charged and discharged using FN tunneling effect.

Memory device research has focused on developing a memory cell that has improved performance characteristics such as shorter programming and erasing times, lower voltages for programming and erasing, longer data retention times and smaller physical dimensions.

### SUMMARY OF THE INVENTION

The object of the present invention is to reduce the voltage and current demanded in programming and erasing and to avoid the occurrence of the interface state to provide a nonvolatile memory cell with low cost, high speed and high reliability.

To achieve the above-mentioned object, the present invention provides a nonvolatile memory cell for injecting carriers into a charge-trapping dielectric layer using point discharge occurring from a polysilicon layer. The structure comprises a substrate having a first conducting type well therein; a source located in a part of the first conducting type well with impurity atoms; a drain located in a part of the first conducting type well with impurity atoms, wherein between the drain and the source is a channel; a first insulating layer disposed on the channel; a first gate disposed over one side of the first insulating layer; a second gate disposed on the first gate and another side of the first insulating layer; and a second insulating layer disposed between the first gate and the second gate. The impurity atoms implanted in the source and drain are second conducting type. For example, the first conducting type is P type and the second conducting type is N type.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A and 1B are schematic illustrations of a prior art nonvolatile memory cell;

FIG. 2 is a schematic illustration of a nonvolatile memory cell in accordance with the preferred embodiment of the present invention;

FIG. 3 is a cross-section showing programming mode of the nonvolatile memory cell according to the preferred embodiment of the present invention;

FIG. 4 is a cross-section showing erase mode of the nonvolatile memory cell according to the preferred embodiment of the present invention; and

FIG. 5 is a cross-section showing read mode of the nonvolatile memory cell according to the preferred embodiment of the present invention.

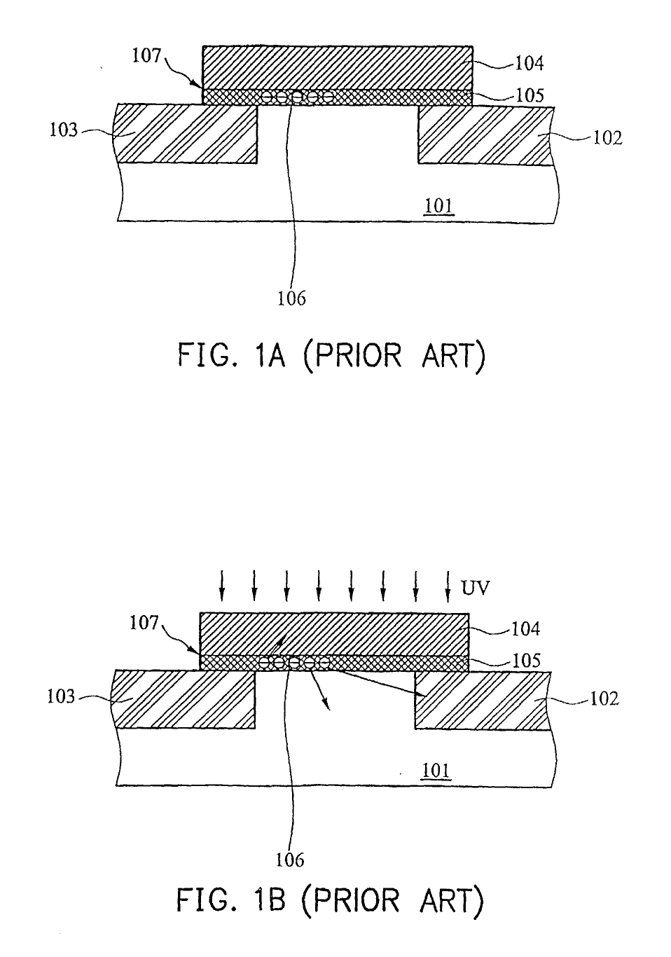

### DETAILED DESCRIPTION OF THE PREFERRED EMBODIMENT A NONVOLATILE MEMORY CELL

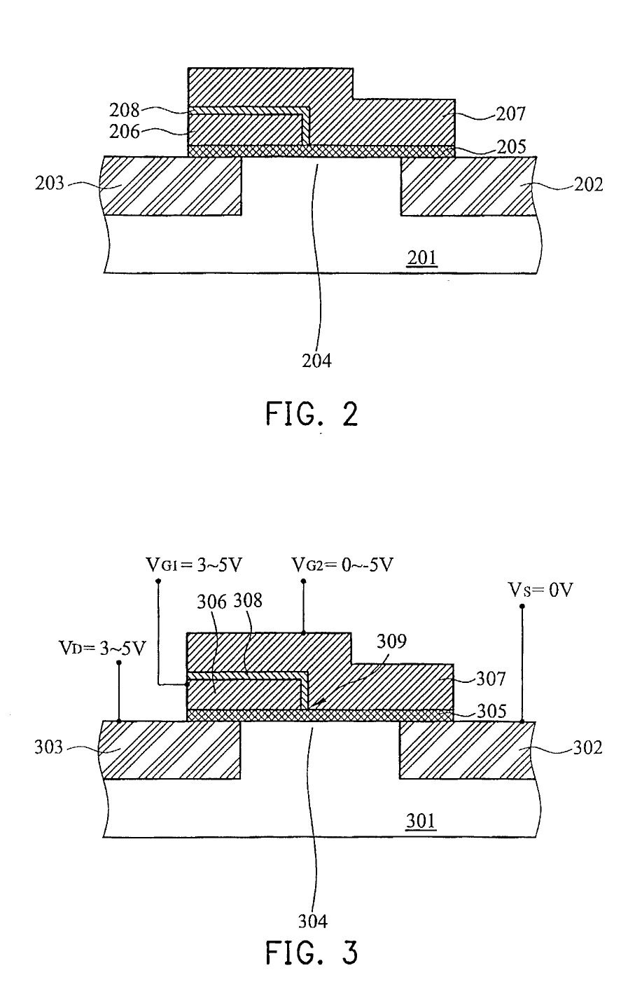

FIG. 2 is a schematic illustration of a nonvolatile memory cell in accordance with the preferred embodiment of the present invention.

A substrate 201 is provided, wherein the substrate 201 has a first conducting type well, such as a P-well or an N-well, therein. The material of the substrate 201 can be a silicon substrate, an amorphous-Si substrate or a poly-Si substrate.

A source 202 is located in a part of the first conducting type well with impurity atoms. The source 202 is a P type doped area or an N type doped area, respectively formed by ion implanting P type dopant, such as B, or N type dopant, such as P.

A drain 203 is located in a part of the first conducting type well with impurity atoms. The drain 203 is a P type doped area or an N type doped area, respectively formed by ion implanting P type dopant, such as B, or N type dopant, such as P. Between the drain 203 and the source 202 is a channel 204.

A first insulating layer 205 is disposed on the channel 204. The first insulating layer 205 is a carrier-trapping dielectric layer of oxide-nitride-oxide (ONO).

A first gate 206 is disposed over one side of the first insulating layer 205. The material of the first gate is poly-Si.

A second gate 207 is disposed on the first gate 206 and another side of the first insulating layer 205. The material of the second gate 207 is poly-Si.

A second insulating layer 208 is disposed between the first gate 206 and the second gate 207. The second insulating layer 208 can be an oxide layer or an oxide-nitride-oxide (ONO) layer.

The writing, reading and erasing operations of the nonvolatile memory cell according to the present invention are given hereafter.

Programming

FIG. 3 is a cross-section showing programming mode of the nonvolatile memory cell according to the preferred embodiment of the present invention.

As shown in FIG. 3, the substrate has a P well 301 therein, the source is a N⁺ type source 302, and the drain is a N⁺ type drain 303. The first insulating layer 305 is disposed on the channel 304 between the drain 303 and the source 302, the drain 303 and the source 302. The first insulating layer 305 is a carrier-trapping dielectric layer of oxide-nitride-oxide (ONO). The first gate 306, composed by poly-Si, is disposed over one side of the first insulating layer 305. The second gate 307, composed of poly-Si, is disposed on the first gate 306 and another side of the first insulating layer 305. The second insulating layer 308 is disposed between the first gate 306 and the second gate 307.

For operating a selected memory cell in a programming mode, a voltage lower than a voltage applied across the drain 303 and the first gate 306 is applied to the second gate 307 and 0V is applied to the source 302, that is V_{S}=0V. The voltage applied to the drain 303 and the first gate 306 are about V_{D}=3˜5 V and V_{G1}=3˜5 V, respectively. The voltage applied to the second gate 307 is about V_{G2}=0˜−5 V. Therefore, electrons in the second gate 307 are injected into the first insulating layer 305 from the edge 309 of the second gate 307.

Erase

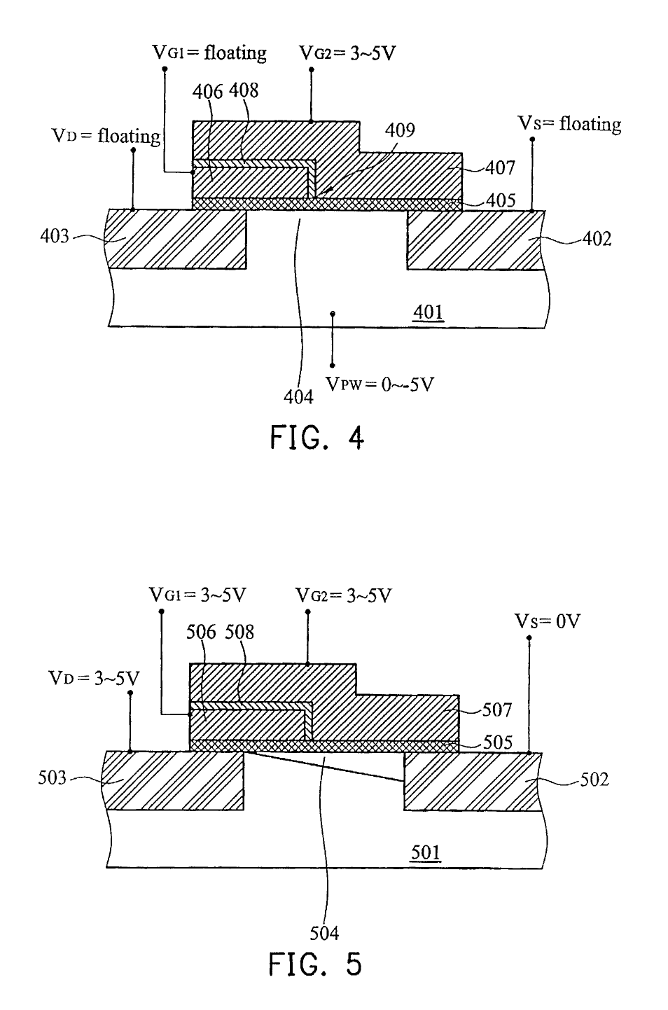

FIG. 4 is a cross-section showing erase mode of the nonvolatile memory cell according to the preferred embodiment of the present invention.

For operating selected memory cells in an erase mode, a voltage higher than a voltage applied to the P well 401 is applied to the second gate 407 and the drain 403, the source 402 and the first gate 406 are floating, that is V_{S}=V_{D}=V_{G1}=floating. The voltage applied to the second gate 407 is about V_{G2}=3˜5 V. The voltage applied to the P well 401 is about V_{PW}=0˜−5 V. Therefore, holes in the second gate 407 are injected into the first insulating layer 405 from the edge 409 of the second gate 407.

Read

FIG. 5 is a cross-section showing read mode of the nonvolatile memory cell according to the preferred embodiment of the present invention.

For operating a selected memory cell in a read mode, a voltage higher than 0V is applied to the second gate 507, the drain 503 and the first gate 506 and 0V is applied to the source 502, that is V_{S}=0V. The voltage applied to the second gate 507, the drain 503 and the first gate 506 are about V_{G2}=3˜5 V, V_{D}=3˜5 V and V_{G1}=3˜5 V, respectively

In the present invention, using point discharge occurring from the second gate 307 or 407, which is word line, carriers can be injected into the first insulating layer 305 or 405, which is a charge-trapping dielectric layer, so as to program or erase the selected memory cell(s). The programming and erasing modes are different from the traditional hot-electron injection mode.

Because the carrier is injected from the edge of the poly gate which have very high E-field, the voltage and current demanded in programming and erasing are reduced, and the interface state is avoided. A nonvolatile memory cell with low cost, high speed and high reliability is thus provided.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A nonvolatile memory cell for injecting carriers into a charge-trapping dielectric layer using point discharge occurring from a polysilicon layer, comprising:
a substrate having a first conducting type well;
a source located in a part of the first conducting type well with impurity atoms;
a drain located in a part of the first conducting type well with impurity atoms, wherein between the drain and the source is a channel;
a first insulating layer disposed on the channel;
a first gate disposed over one side of the first insulating layer;
a second gate disposed on the first gate and another side of the first insulating layer; and
a second insulating layer disposed between the first gate and the second gate.

2. The nonvolatile memory cell as claimed in claim 1, wherein the impurity atoms implanted in the source and drain are second conducting type, and the first and second conducting types are different.

3. The nonvolatile memory cell as claimed in claim 1, wherein the first conducting type well is a P-well or an N-well.

4. The nonvolatile memory cell as claimed in claim 1, wherein the material of the substrate is a silicon substrate, an amorphous-Si substrate or a poly-Si substrate.

5. The nonvolatile memory cell as claimed in claim 1, wherein the source is a P type doped area or an N type doped area.

6. The nonvolatile memory cell as claimed in claim 1, wherein the drain is a P type doped area or an N type doped area.

7. The nonvolatile memory cell as claimed in claim 1, wherein the first insulating layer is a carrier-trapping dielectric layer of oxide-nitride-oxide (ONO).

8. The nonvolatile memory cell as claimed in claim 1, wherein the material of the first gate is poly-Si.

9. The nonvolatile memory cell as claimed in claim 1, wherein the material of the second gate is poly-Si.

10. The nonvolatile memory cell as claimed in claim 1, wherein the second insulating layer is an oxide layer or an oxide-nitride-oxide (ONO) layer.

11. The nonvolatile memory cell as claimed in claim 1, wherein, to operate a selected memory cell in a programming mode, a voltage lower than a voltage applied across the drain and the first gate is applied to the second gate and 0V is applied to the source, thereby injecting electrons in the second gate into the first insulating layer from the edge of the second gate.

12. The nonvolatile memory cell as claimed in claim 11, wherein the voltage applied to the drain is V_{D}=3˜5 V, the voltage applied to the first gate is V_{G1}=3˜5 V, and the voltage applied to the second gate is V_{G2}=0˜−5 V.

13. The nonvolatile memory cell as claimed in claim 1, wherein, to operate selected memory cells in an erase mode, a voltage higher than a voltage applied to the first conducting type well is applied to the second gate, and the drain, the source and the first gate are floating, thereby injecting holes in the second gates into the first insulating layer from the edge of the second gate.

14. The nonvolatile memory cell as claimed in claim 13, wherein the voltage applied to the first conducting type well is V_{PW}=0˜−5 V, and the voltage applied to the first gate is V_{G1}=3˜5 V.

15. The nonvolatile memory cell as claimed in claim 1, wherein, to operate a selected memory cell in a read mode, a positive voltage is applied to the second gate, the drain and the first gate, and 0V is applied to the source.

16. The nonvolatile memory cell as claimed in claim 15, wherein the positive voltage applied to the second gate, the drain and the first gate is V_{G2}=3˜5 V, V_{D}=3˜5 V, and V_{G1}=3˜5 V, respectively.
